(19) United States
(12) Patent Application Publication
(10) Pub. No.: US 2015/0281743 A1
(43) Pub. Date: Oct. 1, 2015

(54) Orthogonal Data Organization for Error Detection and Correction in Serial Video Interfaces

(71) Applicant: Silicon Image, Inc., Sunnyvale, CA (US)

(72) Inventors: Ju Hwan Yi, Sunnyvale, CA (US); Laurence Alan Thompson, Morgan Hill, CA (US)

(21) Appl. No.: 14/673,378

(22) Filed: Mar. 30, 2015

Related U.S. Application Data
(60) Provisional application No. 61/973,837, filed on Apr. 1, 2014.

(51) Int. Cl. H04N 19/89; H03M 13/00

(52) U.S. Cl. CPC H04N 19/89; H03M 13/6312

(57) ABSTRACT

A source device receives digital data comprising uncompressed video data and its associated metadata and compresses the video data. The source device generates an error code for each data word representing the compressed video data and its associated metadata. The data word and its corresponding error code are combined to form a code word. The source device organizes code words of the video data and its metadata into orthogonal data blocks and transmits the data blocks to a sink device. The sink device decodes corrupted data bits in the received data based on analysis of the error codes of the code words in the data blocks. Organizing code words into orthogonal data blocks helps isolate corrupted data bits in data blocks and enables the sink device to detect and correct corrupted data bits resulting from a single transmission error and to detect corrupted data bits resulting from multiple transmission errors.

### CROSS REFERENCE TO RELATED APPLICATIONS

This application claims the benefit of U.S. Provisional Application No. 61/973,837, filed Apr. 1, 2014, which is incorporated by reference in its entirety.

### FIELD

Embodiments of the invention generally relate to the field of digital data transmission over computer networks and particularly to error detection and correction within video channels.

### BACKGROUND

The transmittal of video data over a video channel in modern digital video interface systems is generally subject to some non-zero bit error rate. Modern video interface standards e.g., High-Definition Multimedia Interface (HDMI), Mobile High-Definition Link (MHL) and other audio/video interface standards, support transmission of uncompressed video data and specify an acceptable bit error rate for the transmission of the video data. An occasional bit error in transmitted video data results in a corrupted pixel of the video data. However, the error rate of transmitted video data over a video channel in digital video interface systems based on HDMI, MHL and other audio/video interface standards is generally low such that the occasional bit error in the transmitted video data is not visible to human vision.

Development of modern digital audio/video interface, e.g., Display Stream Compression Standard (DSC), may support transmission of compressed digital video data. Supporting transmission of compressed digital video data by modern digital video interface systems faces challenges of providing efficient error detection and correction in transmitted digital video data because when compressed digital video data is transmitted, a single bit error can corrupt a large block of pixels of the digital video data and may be visible to human vision even if the errors are not frequent to occur.

### SUMMARY

A solution for generating error codes for digital data and detecting corrupted data bits in the digital data at a receiving end is described herein. The solution organizes codes words for the digital data into one or more orthogonal data blocks, where each code word has a data portion representing the content of the digital data and an error correction portion for detecting corrupted data bits in the data portion. By using orthogonal data blocks, the solution enables a sink device to detect and correct corrupted data bits resulting from a single transmission error in a data block and to detect corrupted data bits resulting from multiple transmission errors in a data block.

A source device receives digital data comprising uncompressed video data and its associated metadata and compresses the video data. The source device generates an error code for each data word representing the compressed video data and each data word representing the metadata associated with the video data. The data word and its corresponding error code are combined to form a code word. The source device organizes code words of the video data and its metadata into orthogonal data blocks and transmits the data blocks to a sink device. The sink device detects corrupted data bits in the received data based on analysis of the error codes of the code words in the data blocks. Organizing code words into orthogonal data blocks helps isolate corrupted data bits in data blocks and enables the sink device to detect and correct multiple corrupted data bits resulting from a single transmission error and to detect corrupted multiple data bits resulting from multiple transmission errors.

### BRIEF DESCRIPTION OF THE DRAWINGS

Embodiments of the invention are illustrated by way of example, and not by way of limitation, in the figures of the accompanying drawings in which like reference numerals refer to similar elements:

FIG. 1 is a block diagram illustrating a video interface environment according to one embodiment.

FIG. 2 is a block diagram illustrating an example of digitally line encoded code words of input data during transmission intervals according to one embodiment.

FIG. 3 is a block diagram illustrating an exemplary orthogonal code block having multiple code words according to one embodiment.

FIG. 4A illustrates a first example of no bit errors detected in a transmitted orthogonal code block according to one embodiment.

FIG. 4B illustrates a second example of bit errors detected in all vertical locations of a single column of a transmitted orthogonal code block according to one embodiment.

FIG. 4C illustrates a third example of bit errors detected in some vertical locations of a single column of an orthogonal code block according to one embodiment.

FIG. 4D illustrates a fourth example of bit errors detected in 2 vertical columns of a transmitted orthogonal code block according to one embodiment.

FIG. 5 is a flow chart illustrating a process for generating error codes for input data in a video interface environment according to one embodiment

FIG. 6 is a flow chart illustrating a process for detecting and/or correcting corrupted data bits in received digital data in a video interface environment according to one embodiment.

### DETAILED DESCRIPTION

As used herein, “network” or “communication network” mean an interconnection network to deliver digital media content (including music, audio/video, gaming, photos/images, and others) between devices using any number of technologies, such as Serial ATA (SATA), Frame Information Structure (FIS), etc. A network includes a Local Area Network (LAN), Wide Area Network (WAN), Metropolitan Area Network (MAN), intranet, the Internet, etc. In a network, certain network devices may be a source of digital media content, such as a digital television tuner, cable set-top box, handheld device (e.g., personal device assistant (PDA)), video storage server, and other source device. Such devices are referred to herein as “source devices” or “transmitting devices”. Other devices may receive, display, use, or store digital media content, such as a digital television, home theater system, audio system, gaming system, video and audio storage server, and the like. Such devices are referred to herein as “sink devices” or “receiving devices”.

As used herein, a “video interface environment” refers to an environment including a source device and a sink device coupled by a transmission channel for transmitting video data and metadata associated with the video data. One example of a video interface environment is a HDMI environment, in which a source device (such as a DVD player) is configured to provide media content encoded according to HDMI protocol over an HDMI channel or a MHL3 channel to a sink device (such as television or other display).

It should be noted that certain devices may perform multiple media functions, such as a cable set-top box that can serve as a receiver (receiving information from a cable head-end) as well as a transmitter (transmitting information to a TV) and vice versa. In some embodiments, the source and sink devices may be co-located on a single local area network. In other embodiments, the devices may span multiple network segments, such as through tunneling between local area networks. It should be noted that although generating error codes for digital data and detecting corrupted data bits in received digital data is described herein in the context of a video interface environment, the error generating and detecting techniques described herein are applicable to other types of digital data transfer between a source device and a sink device, such as network data in a networking environment, and the like.

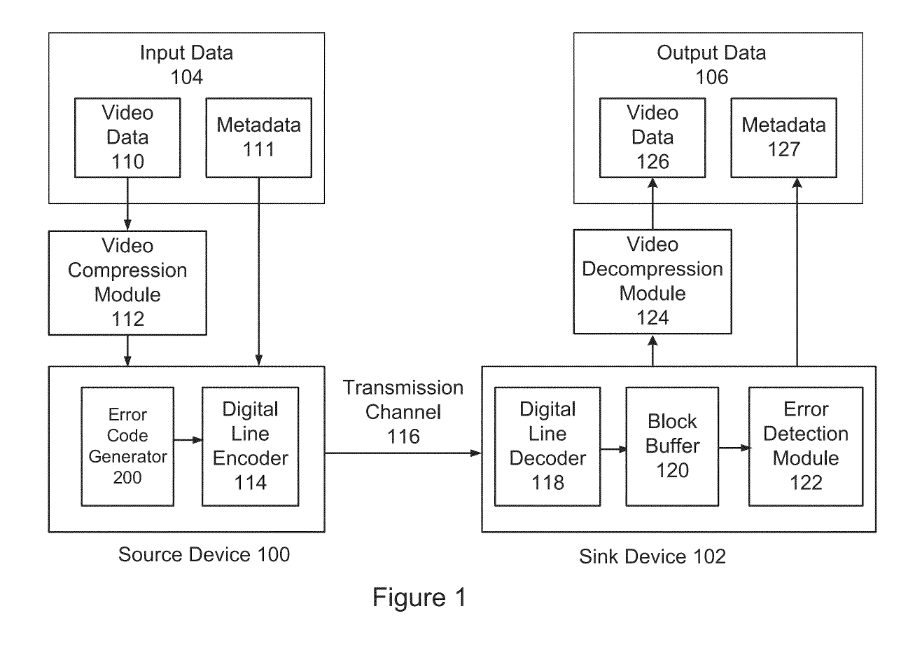

FIG. 1 is a block diagram illustrating a video interface environment according to one embodiment. The environment of FIG. 1 includes a source device 100 coupled to a sink device 102 by a data transmission channel 116. The source device 100 includes a video compression module 112, an error code generator 200 and a digital line encoder 114. The sink device 102 includes a digital line decoder 118, a block buffer 120, an error correction module 122 and a video decompression module 124. The source device 100 receives input data 104 and combines the input data 104 with error codes and transmits the combined data over the transmission channel 116 to the sink device 102. The sink device 102 detects errors in the received data and produces output data 106. The sink device 102 detects and corrects corrupted data bits in the received data resulting from a single transmission error. The sink device 102 also detects and reports corrupted data bits in the received data resulting from multiple transmission errors. Other embodiments of the environment of FIG. 1 can include different and/or additional components than those illustrated herein. For example, the data transmission channel 116 can be any suitable type of video or communications channel, such as an HDMI channel, an MHL channel or another serial-type channel.

In one embodiment, the input data 104 has uncompressed video data 110 and metadata 111 associated with the video data 110. Examples of metadata associated with video data include high dynamic range metadata describing a range of the video data and video compression metadata describing characteristics of the video data, e.g., length of the video, bitrate and frame size of the video and/or characteristics of the encoding used to encode video frames of the video data, e.g., the type of compression algorithm. The input data 104 can be stored on a non-transitory computer-readable storage medium, such as a memory, or received from a source external to the source device 100, for example, from an external video server communicatively coupled to the source device 100 by the Internet or some other type of network.

The video compression module 112 is configured to digitally compress video of the video data 110. The video compression module 112 can implement compression using any known video encoding standards, for example, Display Stream Compression (DSC) of the Video Electronics Standards Association (VESA) and the like. Embodiments of the video compression module 112 may use any video compression schemes known to those of ordinary skills in the art, including, for example, discrete cosine transform (DCT), wavelet transform, quantization and entropy encoding. The video compression module 112 provides the compressed video data to the error code generator 200 for error code generation. The metadata associated with the video data 110 is provided directly to the error code generator 200 for error code generation.

The error code generator 200 generates error codes for the compressed video data and metadata associated with the video data. In one embodiment, the error code generator 200 receives a portion of compressed video data from the video compression module 112, and generates an error code based on the portion of compressed video data. In one embodiment, a portion of the compressed video data has multiple data words, each of which has multiple data bits. For each data word, the error code generator 200 generates an error code, which comprises a predetermined number of syndrome bits (also referred to as “parity bits”). Each data word and its corresponding error code are combined to form an error correction code word (or simply “code word”). In one embodiment, the error code generated by the error code generator 200 is added to the data word, e.g., using a multiplexor prior to being line encoded by the digital line encoder 114 and transmitted over the transmission channel 116.

In one embodiment, the error code generator 200 applies an error correction algorithm to each data word to generate the corresponding syndrome bits. Examples of error correction algorithms that can be used by the error code generator 200 include BCH codes, Reed-Solomon codes and Hamming error correction codes. The error code generator 200 chooses an error correction algorithm based on one or more factors, including, e.g., characteristics of the algorithm (such as cyclic or non-cyclic), size of code word, number of syndrome bits and number of errors within a code word that can be detected and corrected.

The error code generator 200 may further consider error code efficiency when choosing an error correction algorithm to use. The error code efficiency is defined as the ratio of the size of a data word over the size of its corresponding code word. For example, for a code word generated using BCH algorithm, having a total of 255 bits for the code word, 191 bits for the data word, up to 8 errors that can be corrected by the error code, the error code efficiency is 191/255, i.e., 0.749. For another example, for a code word generated using BCH algorithm, having a total of 255 bits for the code word, 247 bits for the data word, correcting 1 error by the error code, the error code efficiency is 247/255, i.e., 0.968.

The error code generator 200 similarly generates error codes for the metadata associated with the video data. For example, the error code generator 200 receives a portion of metadata associated with the video data. The portion of the received metadata has multiple data words, each of which has multiple data bits. For each data word, the error code generator 200 generates an error code, which comprises a predetermined number of syndrome bits. Each data word of the metadata and its corresponding error code are combined to form an error correction code word.

To improve error code efficiency, the error code generator 200 organizes the code words (e.g., the code words for compressed video data and the code words for metadata associated with the video data) according to an orthogonal data organization structure. In one embodiment, the error code generator 200 organizes the code words into one or more orthogonal data blocks. Each orthogonal data block has a number of code words, each of which has a number of data bits and corresponding syndrome bits. The bits that are in a single vertical column are sent to the digital line coder, e.g. the bits labeled 0, 1, 2, 3, 4, 5, 6, 7 from the left most column are sent to the digital line coder first. Next, the same bits 0 through 7 from the 2^{nd} column are sent to the digital line coder second, and so forth.

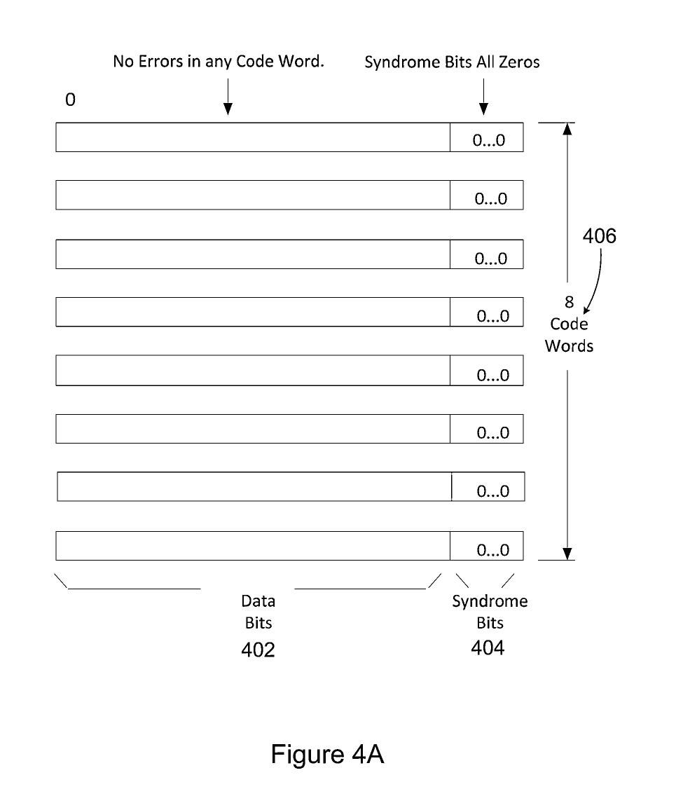

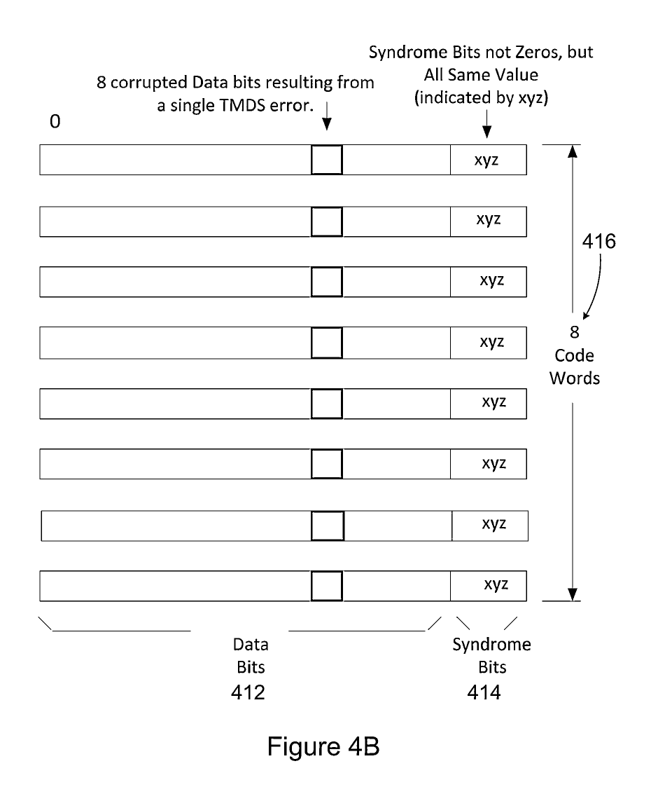

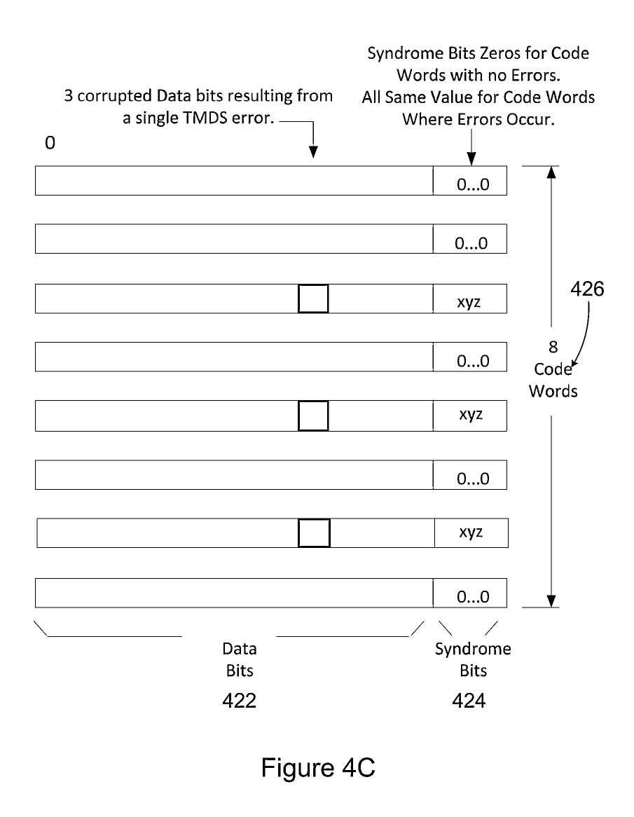

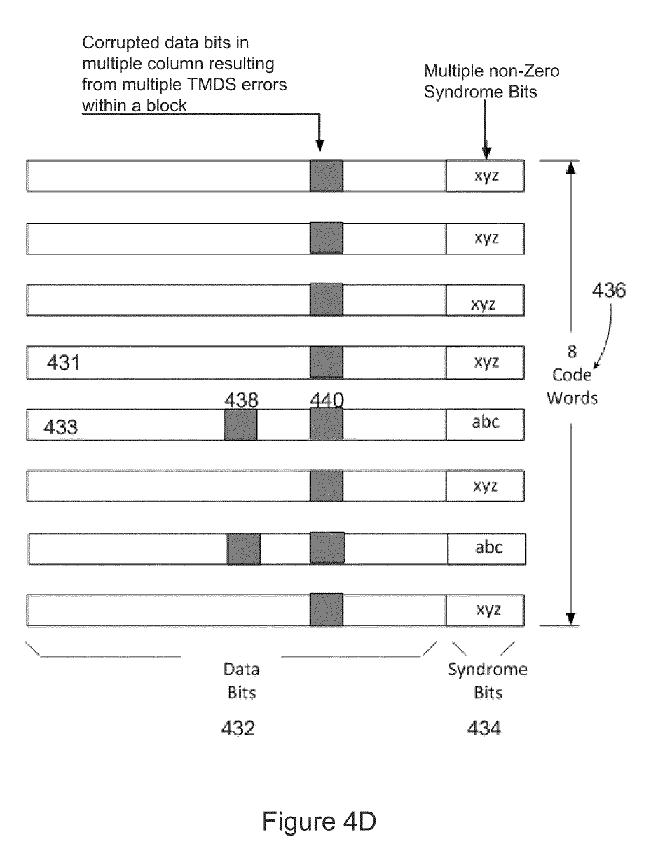

Organizing code words into orthogonal data blocks allows for efficient correction of multiple bit errors. For the system shown in FIG. 1, errors in transmission are errors in the line coded data that reaches the digital line decoder 118. A single bit error in a line code, such as 8b/10b TMDS codes, may result in errors to some or all of the 8 bits of the data symbol after decoding of the corrupted line code. The orthogonal data block structure distributes these multiple errors across multiple code words, where they may appear as a single error per code word. Multiple code words are provided to correct multiple errors. Each code word corrects a single error, resulting in fewer syndrome bits than if the code word corrected multiple bit errors per code word. This results in the ability to correct multiple bit errors in a single 8 bit data symbol, where the data symbol was decoded from a corrupted line code, with the benefit of single bit error correction efficiency. Details of the error detection and correction are further described below with reference to FIG. 4A-FIG. 4D.

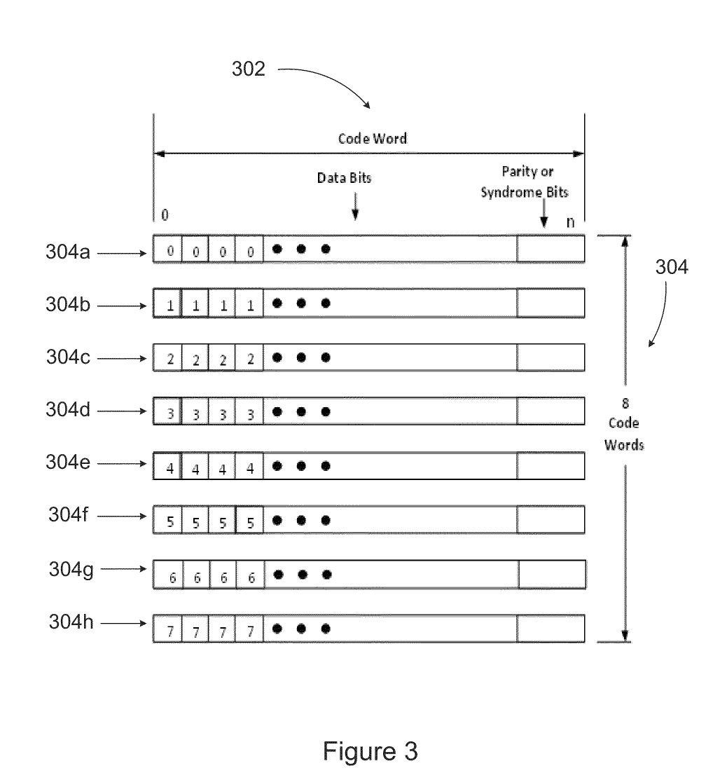

Turning now to FIG. 3, FIG. 3 is a block diagram illustrating an exemplary orthogonal code block 304 having 8 code words 304a-304h according to one embodiment. Other embodiments may have different number of code words in an orthogonal data block. Each of the code words, 304a-304h, has a total of n bits divided between data bits and syndrome bits. The allocation of the total n bits among the data bits and syndrome bits is configurable by the error code generator 200. Examples of bits allocation for a code word of a total of 255 bits include 191 data bits and 64 syndrome bits, which can correct up to 8 errors within the total of 255 bits. Another example is 247 data bits and 8 syndrome bits, which can correct 1 error within the total 255 bits. The error code generator 200 sends bits of the code words from 1 vertical column of orthogonal data block 304 at the same bit position (in other words, a column of bits of the orthogonal data block 304), e.g., 8 vertically aligned bits from code words 304a, 304b, 304c, 304d, 304e, 304f, 304g and 304h, to the digital inline encoder 114 for further processing. The error code generator 200 sends the remaining bits of the orthogonal data block 304, 8 bits at a time, to the digital inline encoder 114 for further processing.

Referring back to FIG. 1, the source device 100 has a digital line encoder 114 for encoding the orthogonal data blocks of code words for the compressed video data and their associated metadata. In one embodiment, the digital line encoder 114 encodes the code words using 8b/10b line encoding according to TMDS standard. Other embodiments of the digital line encoder 114 may use other line encoding schemes, e.g., 16b/18b line encoding. The 8b/10b line encoding maps an 8-bit data symbol to a 10-bit symbol, which helps to achieve DC-balance and provides enough state changes to allow reasonable clock recovery at a receiving end. Applying to the example illustrated in FIG. 3, the digital line encoder 114 takes a column of 8 bits of the orthogonal data block 304 and encodes the 8 bits to a 10-bit data symbol and transmits the bits of the 10-bit data symbol in series to the sink device 102. The digital line encoder 114 repeats the encoding steps on all the remaining columns of the orthogonal data block 304.

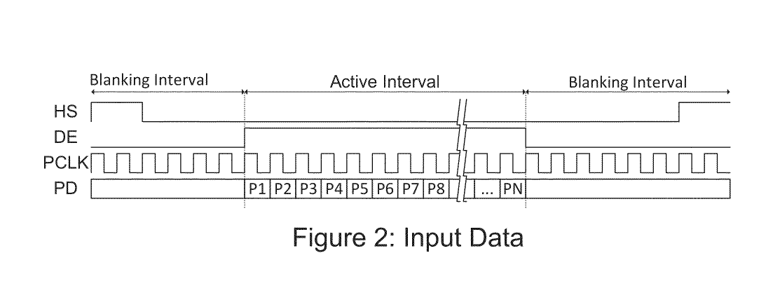

The digital line encoder 114 outputs the line encoded code words onto the transmission channel 116 as a serial bit stream. In one embodiment, the line encoded code words for the compressed video data and the line encoded code words for the metadata associated with the compressed video data are output during different time intervals. For example, the line encoded code words for the compressed video data are output during an active interval and the line encoded code words for the metadata associated with the compressed video data are output during blanking intervals, where the active interval and blanking interval are defined according to the HDMI video interface standard. FIG. 2 is a block diagram illustrating an example of line encoded code words of input data during transmission intervals according to one embodiment.

The digital line decoder 118 of the sink device 102 is configured to receive and decode the line encoded code words from the source device 100. In one embodiment, the digital line decoder 118 applies a line decoding scheme corresponding to the line encoding scheme used by the digital line encoder 114. For example, responsive to the 8b/10b line encoding at the source device 110, the digital line decoder 118 converts a 10-bit data symbol to an 8-bit data symbol. The block buffer 120 is a memory or other storage medium configured to buffer code words decoded by the digital line decoder 118.

The video decompression module 124 is configured to decode video data received from the error correction module 122. The decoding process performed by the video decompression module 124 is an inversion of each stage of the encoding process performed by the video compression module 112 (except the quantization stage in lossy compression). For example, the video decompression module 124 performs decoding process according to the DSC coding standard responsive to the video compression module 112 encoding the video frame according to the DSC coding standard.

The error correction module 122 is configured to receive line decoded code words from the block buffer 120 and to detect and correct errors (i.e., corrupted data bits) in the code words. The transmittal of video data over a video channel in modern digital video interface systems is generally subject to some non-zero bit error rate. For example, a single bit error in a 10-bit TMDS data symbol transported over a transmission channel, e.g., the transmission channel 116, can corrupt up to all 8 bits in the line decoded data. With the code words organized in orthogonal data blocks, the error correction module 122 is enabled to detect corrupted data bits in the code words and correct multiple corrupted data bits resulting from a single TMDS transmission error.

In one embodiment, the error correction module 122 detects one or more errors in code words of a data block by checking the values of syndrome bits in each code word and differences among the values of the syndrome bits of the code words. Responsive to the values of the syndrome bits of all code words in the data block being a predefined value indicating error free, e.g., zero, the error correction module 122 determines that the data block does not have any errors. Responsive to the syndrome bits of all code words being non-zero, but having the same value, the error correction module 122 determines that the data block has 8 corrupted data bits resulting from a single transmission error. Responsive to the syndrome bits of multiple code words (but not all code words) being non-zero and the syndrome bits of the remaining code words having the value of zero, the error correction module 122 determines that the data blocks has a number of corrupted data bits resulting from a single transmission error, and the number of the corrupted data bits equals to the number of the code words having non-zero syndrome bits. Response to the syndrome bits of all code words being non-zero and the non-zero values of the syndrome bits being different, the error correction module 122 determines that there are multiple corrupted data bits in the data block resulting from multiple transmission errors.

Responsive to corrupted data bits resulting from a single transmission error, the error correction module 122 corrects the corrupted data bits in the code words. Any error correction schemes known to those of ordinary skill in the art can be used by the error correction module 112 for correcting the corrupted data bits. For example, responsive to code words having corrupted data bits in the data block resulting from a single transmission error, the error correction module 122 accesses the line decoded data stored in the block buffer 120 and corrects the corrupted bits by replacing the each corrupted bit with its inverse. Responsive to multiple corrupted data bits resulting from multiple transmission errors, the error correction module 122 detects the corrupted data bits and reports the detected errors for further processing.

FIG. 4A-FIG. 4D illustrate four examples of bit errors detected in transmitted digital data by the error correction module 122 according to one embodiment. In the illustrated examples, the transmitted digital data are line decoded symbols for the compressed video data and its associated metadata; the line decoding scheme used is 10b/8b decoding according to the TMDS standard. Each example shown in FIG. 4A through FIG. 4D shows an orthogonal data block of 8 code words.

FIG. 4A illustrates an example where there are no corrupted data bits in any code word of the received orthogonal data block. The error correction module 122 checks the values of syndrome bits in each code word. Responsive to the values of the syndrome bits of all code words in the data block being a predefined value indicating error free, e.g., zero, the error correction module 122 determines that the data block does not have any error. In the example illustrated in FIG. 4A, the syndrome bits 404 of all 8 code words are all zero, which is the predefined value representing error free data transmission. Based on the values of the syndrome bits of all 8 code words, the error correction module 122 determines that the data block does not have any corrupted data bits.

FIG. 4B illustrates a second example where there are 8 corrupted data bits in the data block resulting from a single TMDS transmission error. The error correction module 122 detects the corrupted data bits by checking the values of syndrome bits in each code word and comparing the values of the syndrome bits. In the example illustrated in FIG. 4B, the syndrome bits 404 of all 8 code words are all non-zero and have same value, e.g., value “xyz.” Responsive to the syndrome bits of all code words being non-zero, but having the same value, the error correction module 122 determines that the data block has 8 corrupted data bits resulting from a single TMDS transmission error. The same non-zero value of the syndrome bits in all 8 code words indicate that the corrupted data bit in each code word is located at the same bit position in each code word. The error correction module 122 corrects the corrupted the data bits in all 8 code words, e.g., flipping the corrupted data bit in each data word.

FIG. 4C illustrates a third example where not all the 8 code words have corrupted data bits. The error correction module 122 detects the corrupted data bits by checking the values of syndrome bits in each code word and comparing the values of the syndrome bits. Based on the checking and comparison, the error correction module 122 detects 3 code words having non-zero syndrome bits, but the same value, and the syndrome bits of the remaining 5 code words having zero syndrome bits indicating error free. The 3 code word having non-zero syndrome bits are determined to have a corrupted bit in each code word resulting from a single TMDS transmission error. The error correction module 122 corrects the corrupted data bits in the identified 3 code words.

FIG. 4D illustrates a fourth example where the data block has multiple corrupted data bits resulting from multiple transmission errors. In the example illustrated in FIG. 4D, all 8 code words having at least one corrupted data bit indicated by the non-zero syndrome bits of all 8 code words. In the example illustrated in FIG. 4D, two code words have multiple corrupted data bits in each code word indicated by a different value of the syndrome bits (e.g., value “abc”) from the syndrome bits (e.g., value “xyz”) of the remaining code words. For example, code word 433 has two corrupted data bits, where its corresponding syndrome bits have a value of “abc” instead of “xyz.” Based on the checking and comparison, the error correction module 122 detects that the data block 436 has multiple corrupted data bits resulting from multiple TMDS transmission errors and reports the detection for further processing.

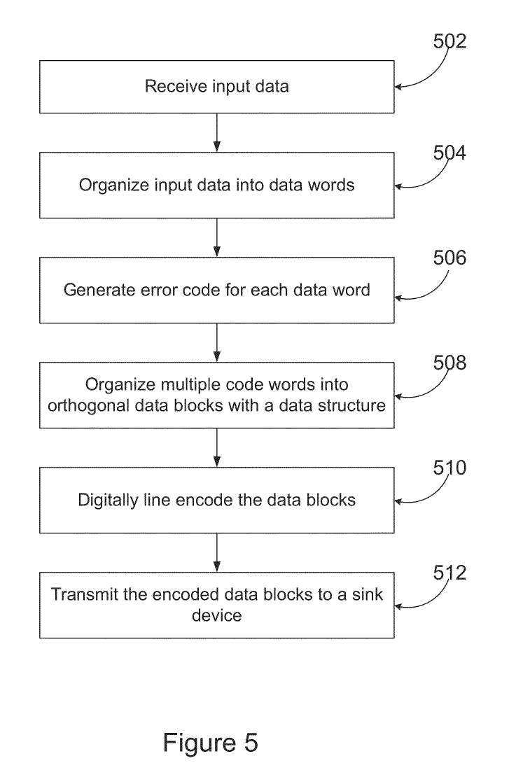

FIG. 5 is a flow chart illustrating a process for generating error codes for input data in a video interface environment according to one embodiment. Initially, the source device 100 receives 502 input data including uncompressed video data and its associated metadata. A video compression module of the sink device 100 compresses the video data according to a video compression standard, e.g., VESA/DSC and provides the compressed video data to an error code generator of the source device 110 for generating syndrome bits. The metadata associated with the video data is also provided to the error code generator for syndrome bits generation.

The error code generator generates error codes comprising a number of syndrome bits for the compressed video data and its metadata a portion a time. In one embodiment, a portion of the compressed video data/metadata has multiple data words, each of which has a predefined number of data bits. For each data word, the error code generator generates 506 an error code having multiple syndrome bits and combines the data word with its corresponding error code into a code word. The size of the code word is configurable, e.g., 255 bits in total. Multiple code words are organized into an orthogonal data block, which helps isolate transmission errors in the code words.

Prior to transmission of the orthogonal data blocks to the sink device 102, a digital line encoder of the source device 100 line encodes 510 the code words, e.g., using 8b/10b line coding of TMDS standard. Other line coding schemes, such as 16b/18b, can be used by the digital line encoder of the source device 100. The source device 100 transmits 512 the line encoded code words over a transmission channel, e.g., a HDMI serial connection, to the sink device 102.

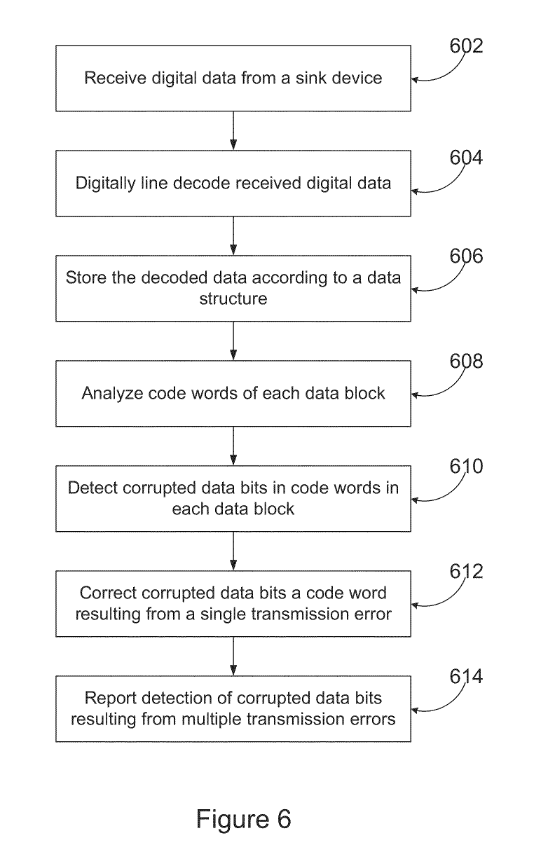

FIG. 6 is a flow chart illustrating a process for detecting and/or correcting corrupted data bits in received digital data in a video interface environment according to one embodiment. Initially, the sink device 102 receives 602 digital data, e.g., a series of code words for video data and its associated metadata, from the sink device 100. A digital line decoder of the sink device 102 line decodes 604 the received data according to a digital line decoding scheme, which corresponds to the line encoding scheme used by the digital line encoder of the source device 100. The sink device 102 stores 606 the line decoded data in a computer storage medium, e.g., a block buffer 120. In one embodiment, the line decoded data are organized into multiple data blocks according to a data structure, e.g., an orthogonal organization data structure. Each data block has multiple code words, e.g., 8 code words.

An error correction module of the sink device 102 analyzes 608 the code words and detects 610 the corrupted data bits in the code words of each data block. In one embodiment, the error correction module detects corrupted data bits in the code words of a data block by checking the syndrome bits of all code words of the data block, comparing the syndrome bits with a predefined value representing error free and comparing the values of the syndrome bits of the code words among themselves. Based on the checking and comparison, the error correction module detects the corrupted bits in the data block as illustrated through FIG. 4A and FIG. 4D.

Responsive to the corrupted data bits of a data block resulting from a single transmission error, e.g., an error to a 10-bit TMDS data symbol, the error correction module corrects 612 the corrupted data bits, e.g., by flipping those bits determined to be incorrect. Responsive to the corrupted data bits of a data block resulting from multiple transmission errors, the error correction module reports 614 the detection of corrupted data bits in the data block for further processing.

The foregoing description of the embodiments has been presented for the purpose of illustration; it is not intended to be exhaustive or to limit the embodiments to the precise forms disclosed. Persons skilled in the relevant art can appreciate that many modifications and variations are possible in light of the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the embodiments be limited not by this detailed description, but rather by any claims that issue on an application based herein. Accordingly, the disclosure of the embodiments is intended to be illustrative, but not limiting.

What is claimed is:

1. A method for generating error codes for digital data, the method comprising:
receiving the digital data, the digital data comprising uncompressed video data and metadata associated with the uncompressed digital video data;
encoding the uncompressed video data to generate compressed video data, the compressed video data having a plurality of data words;
generating an error code for each of the plurality of data words of the compressed video data and for each of a plurality of data words of the metadata;
for each data word, combining the data word and its corresponding error code to form a code word; and
organizing a plurality of code words into one or more data blocks according to a data structure.

2. The method of claim 1, wherein a code word comprise a data portion and an error correction portion, the data portion of the code word having a plurality of data bits representing digital content of the code word and the error correction portion having a plurality of syndrome bits for detecting errors in the data portion.

3. The method of claim 1, wherein generating an error code for a data word of the digital data comprises:
applying an error correction scheme to the data word; and
generating an error code for the data word based on the application of the error correction scheme.

4. The method of claim 1, wherein organizing the plurality of code words into one or more data blocks according to a data structure comprises:
selecting a number of code words to form a data block, the data block having a width and height, the width of the data block being equal to the size of the code word and the height of the data block being equal to the number of data bits encoded into each line code symbol; and
selecting corresponding bits from the selected code words at a same bit position of the data block for digital line encoding.

5. The method of claim 4, wherein the number of code words of a data block is equal to the number of data bits encoded into each line code symbol and the number of bit errors resulting from a single transmission error that are corrected in the data block is equal to the number of data bits encoded into each line code symbol.

6. The method of claim 1, further comprising:
digitally line encoding the data blocks; and
transmitting the line encoded data blocks in series to a sink device.

7. The method of claim 6, wherein line encoding a data block comprises one of the following:
encoding eight data bits of the data block into a ten-bit representation; and
encoding sixteen data bits of the data block into an eighteen-bit representation.

8. A method for detecting errors in transmitted digital data, the method comprising:
receiving the digital data, the digital data comprising code words representing video data and code words representing metadata associated with the video data;
line decoding the code words of the digital data and organizing the code words into a plurality of data blocks based on a data structure, each data block having a plurality of code words;
analyzing the code words in each data block; and
detecting one or more corrupted data bits in each data block.

9. The method of claim 8, wherein detecting a bit error in a code word of the digital data comprises:
analyzing error correction portion of the code word;
comparing the error correction code with a predetermined threshold code;
comparing the error correction portion of the code word with corresponding error correction portions of the remaining code words in the same data block; and
detecting the bit error based on the comparisons.

10. The method of claim 8, further comprising:
responding to the corrupted data bits in a data block resulting from a single transmission error, correcting the corrupted data bits; and
responding to the corrupted data bits in a data block resulting from multiple single transmission errors, reporting detection of the corrupted data bits.

11. A non-transitory computer readable storage medium storing computer program instructions for generating error codes for digital data, the computer program instructions comprising instructions that when executed by a computer processor cause the computer processor to:
receive the digital data, the digital data comprising uncompressed video data and metadata associated with the uncompressed digital video data;
encode the uncompressed video data to generate compressed video data, the compressed video data having a plurality of data words;
generate an error code for each of the plurality of data words of the compressed video data and for each of a plurality of data words of the metadata;
for each data word, combine the data word and its corresponding error code to form a code word; and
organize a plurality of code words into one or more data blocks according to a data structure.

12. The computer readable storage medium of claim 11, wherein a code word comprise a data portion and an error correction portion, the data portion of the code word having a plurality of data bits representing digital content of the code word and the error correction portion having a plurality of syndrome bits for detecting errors in the data portion.

13. The computer readable storage medium of claim 11, wherein the computer program instructions for generating an error code for a data word of the digital data comprise instructions that when executed by the computer processor cause the computer processor to:
apply an error correction scheme to the data word; and
generate an error code for the data word based on the application of the error correction scheme.

14. The computer readable storage medium of claim 11, wherein the computer program instructions for organizing the plurality of code words into one or more data blocks according to a data structure comprise instructions that when executed by the computer processor cause the computer processor to:
select a number of code words to form a data block, the data block having a width and height, the width of the data block being equal to the size of the code word and the height of the data block being equal to the number of data bits encoded into each line code symbol; and
select corresponding bits from the selected code words at a same bit position of the data block for digital line encoding.

15. The computer readable storage medium of claim 11, wherein the number of code words of a data block is the number of data bits encoded into each line code symbol and the number of bit errors resulting from a single transmission error that are corrected in the data block is the number of data bits encoded into each line code symbol.

16. The computer readable storage medium of claim 11, further comprising computer program instructions that when executed by the computer processor cause the computer processor to:
digitally line encode the data blocks; and
transmit the line encoded data blocks in series to a sink device.

17. The computer readable storage medium of claim 16, wherein the computer program instructions for line encoding a data block comprise instructions that when executed by the computer processor cause the computer processor to encode as one of the following:
encode eight data bits of the data block into a ten-bit representation; and
encode sixteen data bits of the data block into an eighteen-bit representation.

18. A non-transitory computer readable storage medium storing computer program instructions for detecting errors in transmitted digital data, the computer program instructions comprising instructions that when executed by a computer processor cause the computer processor to:
receive the digital data, the digital data comprising code words representing video data and code words representing metadata associated with the video data;
line decode the code words of the digital data and organizing the code words into a plurality of data blocks based on a data structure, each data block having a plurality of code words;
analyze the code words in each data block; and
detect one or more corrupted data bits in each data block.

19. The computer readable storage medium of claim 18, wherein the computer program instructions for detecting a bit error in a code word of the digital data comprise instructions that when executed by the computer processor cause the computer processor to:
analyze error correction portion of the code word;
compare the error correction code with a predetermined threshold code;
compare the error correction portion of the code word with corresponding error correction portions of the remaining code words in the same data block; and
detect the bit error based on the comparisons.

20. The computer readable storage medium of claim 18, further comprising computer program instructions that when executed by the computer processor cause the computer processor to:
responding to the corrupted data bits in a data block resulting from a single transmission error, correct the corrupted data bits; and
responding to the corrupted data bits in a data block resulting from multiple single transmission errors, report detection of the corrupted data bits.
